(19) United States
(12) Patent Application Publication
(10) Pub. No.: US 2016/0218138 A1
(43) Pub. Date: Jul. 28, 2016

(54) SOLID-STATE IMAGE PICKUP DEVICE AND METHOD FOR MANUFACTURING A SOLID-STATE IMAGE PICKUP DEVICE

(71) Applicant: Kabushiki Kaisha Toshiba, Minato-ku (JP)

(72) Inventor: Amane OISHI, Oita (JP)

(73) Assignee: Kabushiki Kaisha Toshiba, Minato-ku (JP)

(21) Appl. No.: 14/982,553

(22) Filed: Dec. 29, 2015

(30) Foreign Application Priority Data
Jan. 23, 2015 (JP) 2015-011336

(51) Int. Cl. H01L 27/146; H01L 29/423

(52) U.S. Cl. CPC H01L 27/14643; H01L 27/14607; H01L 27/14614; H01L 29/4236; H01L 27/14689; H01L 29/42376

(57) ABSTRACT

A solid-state image pickup device includes a semiconductor layer, a photoelectric conversion element, floating diffusion, a plurality of gates, and a semiconductor region. The photoelectric conversion element is provided in the semiconductor laver. The floating diffusion is provided at a shallow position at a side of one surface of the semiconductor layer. The plurality of gates are each provided adjacent to the floating diffusion and extend toward the photoelectric conversion element in a direction of a depth of the semiconductor layer. The semiconductor region is provided between the gates to face the floating diffusion.

### CROSS-REFERENCE TO RELATED APPLICATIONS

This application is based upon and claims the benefit of priority front Japanese Patent Application No. 2015-011336, filed on Jan. 23, 2015; the entire content of which are incorporated herein by reference.

### FIELD

Embodiments described herein relate generally to a solid-state image pickup device and a method for manufacturing a solid-state image pickup device.

### BACKGROUND

Conventionally, a solid-state image pickup device includes a photoelectric conversion element that is provided in a semiconductor layer and photoelectrically converts incident light into a signal charge, and a floating diffusion that temporarily retains the signal charge that is transferred from the photoelectric conversion element.

Such a solid-state image pickup device may include a photoelectric conversion element that is provided at a position deeper than that of a floating diffusion in a semiconductor layer, and one trench gate that is provided adjacent to the floating diffusion and extends toward the photoelectric conversion element.

A solid-state image pickup device that includes one trench gate applies a predetermined transfer voltage to the trench gate, and thereby, forms a channel on a side face of the trench gate at a side of a floating diffusion. The solid-state image pickup device transfers a signal charge from a photoelectric conversion element to the floating diffusion through the channel. However, in such a solid-state image pickup device, a transfer characteristic of a signal charge from the photoelectric conversion element to the floating diffusion is insufficient.

### BRIEF DESCRIPTION OF THE DRAWINGS

FIG. 1 is a block diagram illustrating a general configuration of a digital camera that includes a solid-state image pickup device according to an embodiment.

FIG. 2 is a block diagram illustrating a general configuration of a solid-state image pickup device according to the embodiment.

FIG. 3 is a diagram illustrating a pixel cell according to the embodiment when transparently viewed from a side opposite to a light-receiving face thereof.

FIG. 4 is a diagram illustrating a cross section of a pixel cell according to the embodiment and a transfer path of a signal charge therein.

FIG. 5 is a diagram illustrating a cross section of a pixel cell according to the embodiment and a transfer path of a signal charge therein.

FIG. 6 is a diagram illustrating a cross section of a pixel cell according to the embodiment and a transfer path of a signal charge therein.

FIG. 7 is a diagram illustrating an energy barrier of a transfer transistor according to the embodiment in an ON/OFF state thereof.

FIG. 8A to FIG. 11B are cross-sectional diagrams illustrating a process for manufacturing a pixel cell according to the embodiment.

FIG. 12A and FIG. 12B are diagrams illustrating pixel cello according to variation examples of the embodiment.

### DETAILED DESCRIPTION

According to the present embodiment, a solid-state image pickup device is provided. A solid-state image pickup device according to one embodiment includes a semiconductor layer, a photoelectric conversion element, a floating diffusion, a plurality of gates, and a semiconductor region. The photoelectric conversion element is provided in the semiconductor layer. The floating diffusion is provided at a shallow position at a side of one surface of the semiconductor layer. The plurality of gates are each provided adjacent to the floating diffusion and extend toward the photoelectric conversion element in a direction of a depth of the semiconductor layer. The semiconductor region is provided between the gates to face the floating diffusion.

Hereinafter, a solid-state image pickup device and a method for manufacturing a solid-state image pickup device according to an embodiment will be described in detail, with reference to the accompanying drawings. The present invention is not limited to this embodiment.

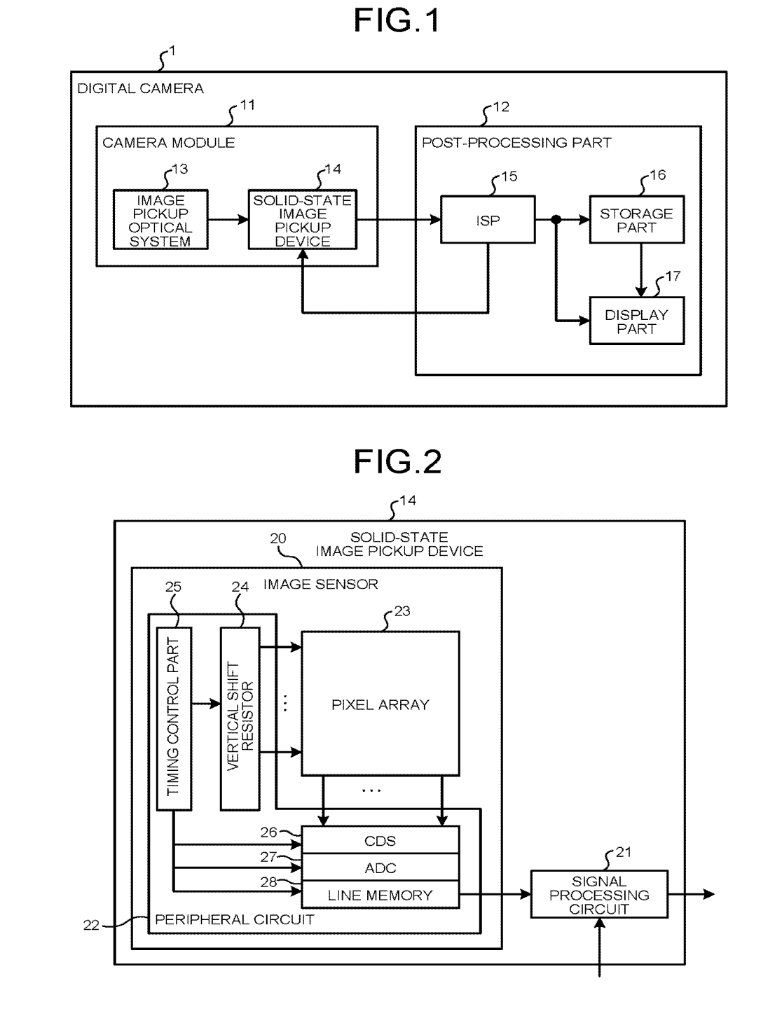

FIG. 1 is a block diagram illustrating a general configuration of a digital camera 1 that includes a solid-state image pickup device 14 according to the embodiment. As illustrated in FIG. 1, the digital camera 1 includes a camera module 11 and a post-processing part 12.

The camera module 11 includes an image pickup optical system 13 and a solid-state image pickup device 14. The image pickup optical system 13 receives light from an object and forms an object image. The solid-state image pickup device 14 picks up the object image that is formed by the image pickup optical system 13, and outputs an image signal obtained by an image pickup to the post-processing part 12. The camera module 11 is applied to, for example, electronic equipment such as a camera-equipped mobile terminal, other than the digital camera 1.

The post-processing part 12 includes an ISP (Image Signal Processor) 15, a storage part 16, and a display part 17. The ISP 15 executes signal processing for an image signal that is input from the solid-state image pickup device 14. The ISP 15 executes, for example, a high image quality process ouch as a noise elimination process, a defective pixel correction process, or a resolution conversion process.

The IPS 15 outputs an image signal after signal processing to the storage part 16, the display part 17, and a signal processing circuit 21 described later (see FIG. 2) that is included in the solid-state image pickup device 14 in the camera module 11. An image signal that is provided as feedback from the IPS 15 to the camera module 11 is used for adjustment or control of the solid-state image pickup device 14.

The storage part 16 stores, as an image, an image signal that is input from the ISP 15. The storage part 16 outputs an image signal for a stored image to the display part 17 depending on a user operation or the like. The display part 17 displays an image depending on an image signal that input from the IPS 15 or the storage part 16. The display part 17 is, for example, a liquid crystal display.

Next, the solid state image pickup device 14 that is included in the camera module 11 will be described with reference to FIG. 2. FIG. 2 is a block diagram illustrating a general configuration of the solid-state image pickup device 14 according to the embodiment. As illustrated in FIG. 2, the solid-state image pickup device 14 includes an image sensor 20 and a signal processing circuit 21.

Herein, a case will be described where the image sensor 20 is a so-called back side illumination type CMOS (Complementary Metal Oxide Semiconductor) image sensor, where an interconnection layer is formed at a side of a face opposite to an incident-light incident face of photoelectric conversion element that photoelectrically converts incident light. The image sensor 20 according to the present embodiment is not limited to the back side illumination type CMOS image sensor and may be a front side illumination type CMOS image sensor.

The image sensor 20 includes a peripheral circuit 22 that is mainly composed of an analog circuit, and a pixel array 23. The peripheral circuit 22 includes a vertical shift resistor 24, a timing control part 25, a CDS (correlated double sampling part) 26, an ADC (analog-digital conversion part) 27, and a line memory 28.

The pixel array 23 is provided in an image pickup region of the image sensor 20. In the pixel array 23, a plurality of photoelectric conversion elements that correspond to respective pixels of a picked up image are arrayed like a two-dimensional array (like a matrix) in a horizontal direction (row direction) and a vertical direction (column direction).

Each photoelectric conversion element is, for example, a photodiode that is formed by P-N junction of a P-type semiconductor region that is of a first conductivity type and an N-type semiconductor region that is of a second conductivity type, and generates and stores a signal charge (for example, an electron) corresponding to an amount of incident light.

A signal charge stored in a photoelectric conversion element is transferred to and retained in a floating diffusion through a charge transfer region in a case where a predetermined voltage is applied to a transfer gate that is provided for each photoelectric conversion element.

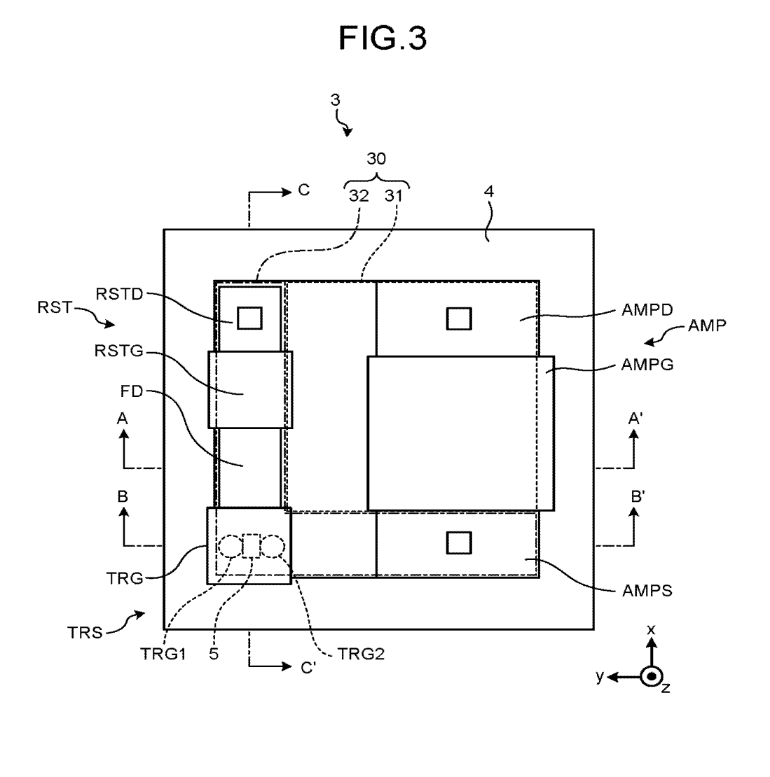

In the pixel array 23, configurations of such a transfer gate and a neighborhood of the transfer gate are improved, and thereby, a transfer characteristic of a signal charge from a photoelectric conversion element to a floating diffusion is improved while an inflow of dark current into the floating diffusion is suppressed. Details of a transfer gate and a neighborhood of the transfer gate will be described later, with reference to FIG. 3 and the subsequent drawings.

The timing control part 25 is connected to the vertical shift resistor 24, the CDS 26, the ADC 27, and the line memory 28, and executes timing control of operations of the vertical shift resistor 24, the CDS 26, the ADC 27, and the line memory 28.

The vertical shift resistor 24 is a processing part that outputs, to the pixel array 23, a selection signal for sequentially selecting, line by line, photoelectric conversion elements to read signal charges therefrom, among a plurality of photoelectric conversion elements that are two-dimensionally arrayed like an array (matrix).

The pixel array 23 outputs a signal charge stored in each of photoelectric conversion elements that are selected line by line depending on a selection signal that is input from the vertical shift resistor 24, from the photoelectric conversion elements the CDS 26, as a pixel signal that indicates brightness of each pixel.

The CDS 26 is a processing part that eliminates, by correlated double sampling, noise from, and outputs to the ACC 27, pixel signals that are input from the pixel array 23. The ADC 27 is a processing part that converts analog pixel signals that are input from the CDS 26 to, and outputs to the line memory 28, digital pixel signals. The line memory 28 is a processing part that temporarily retains, and outputs to the signal processing circuit line by line of the photoelectric conversion elements of the pixel array 23, pixel signals that are input from the ADC 27.

The signal processing circuit 21 is a processing part that is mainly composed of a digital circuit, executes predetermined signal processing for pixel signals that are input from the line memory 28, and outputs pixel signals after signal processing to the post-processing part 12 as an image signal. The signal processing circuit 21 executes, for example, signal processing such as lens shading correction, flaw correction, or noise reduction processing, for the pixel signals.

Thus, the image sensor 20 executes an image pickup in such a manner that the plurality of photoelectric conversion elements that are arrayed in the pixel array 23 photoelectrically convert incident light into, and store, an amount of signal charges that corresponds to an amount of received light, and the peripheral circuit 22 reads signal charges stored in respective photoelectric conversion elements as pixel signals.

Next, a configuration of a pixel cell according to the embodiment will be described with reference to FIG. 3. FIG. 3 is a diagram illustrating a pixel cell 3 according to the embodiment when transparently viewed from a side opposite to a light receiving face thereof. FIG. 3 illustrates the pixel cell 3 that corresponds to one pixel of a picked up image.

FIG. 3 illustrates a situation that a multilayer interconnection layer and a supporting substrate that will be described later are eliminated in order to clarify arrangement of components of the pixel cell 3. Hereinafter, descriptions will be provided while a normal direction of a light-receiving face of a pixel cell is an x-direction and two directions perpendicular to each other in a plane orthogonal to a z-direction are the x-direction and a y-direction.

As illustrated in FIG. 3, the pixel cell 3 includes a photoelectric conversion element 30 that is provided at a center thereof and an element separation region 4 that surrounds side faces of the photoelectric conversion element 30. The photoelectric conversion element 30 is provided inside a semiconductor layer and includes a P-type semiconductor region 31 with a quadrangular prismatic shape that extends in a −z direction, and an N-type semiconductor region 32 that is provided to have an L-shape in a planar view along two adjacent side faces of the P-type semiconductor region 31.

The photoelectric conversion element 30 is a photodiode that is formed by P-N junction of the P-type semiconductor region 31 and the N-type semiconductor region 32, and generates, and stores in the N-type semiconductor region 32, a signal charge (for example, an electron) corresponding to an amount of incident light. Hereinafter, the N-type semiconductor region 32 will be described as a charge storage region 32.

The pixel cell 3 includes a floating diffusion FD, a transfer transistor TRS, a reset transistor RST, and an amplification transistor AMP. The floating diffusion FD is a region doped with an N-type impurity, and is provided at a shallow position at a side of one surface of the semiconductor layer. For example, the floating diffusion FD is provided at a position shallower than that of the charge storage region 32 in the semiconductor layer, that is, a position at a + side f the c-axis with respect to the charge storage region 32.

The pixel cell 3 includes a drain RSTD of the reset transistor RST, a source PS of the amplification transistor AMP, and a drain AMPD of the amplification transistor AMP at positions at a depth comparable with that of the floating diffusion FD in the semiconductor layer.

Any of the drain RSTD of the reset transistor RST, the source AMPS of the amplification transistor AMP, and the drain AMPD of the amplification transistor AMP is a region doped with an N-type impurity.

The transfer transistor TRS includes a transfer gate TRG, and transfers a signal charge from the charge storage region 32 to the floating diffusion FD in a case where a predetermined voltage is applied to the transfer gate TRG.

The amplification transistor AMP includes an amplification gate AMPG that is connected to the floating diffusion FD, and causes a pixel signal corresponding to an electric potential of the floating diffusion FD to flow between the source AMPS and the drain AMPD, thereby amplifying a signal charge. This pixel signal is output to the CDS 26 (see FIG. 2).

The reset transistor RST includes a reset gate RSTG, and transfers a signal charge from the floating diffusion FD to the drain RSTD to reset an electric potential of the floating diffusion FD, in a case where a predetermined voltage is applied to the reset gate RSTG.

Herein, the transfer gate TRG according to the embodiment includes a gate (that will hereinafter be described as a “first trench gate TRG1”) that extends toward the charge storage region 32 in a direction of a depth of the semiconductor layer and has a solid circular cylindrical shape, and similarly, a gate (that will hereinafter be described as a “second trench gate TRG2”) that extends toward the charge storage region 32 in direction of a depth of the semiconductor layer and has a solid circular cylindrical shape, each of which is provided adjacent to the floating diffusion FD.

The pixel cell 3 includes a P-type channel region 5 that faces the floating diffusion FD, between the first trench gate TRG1 and the second trench gate TRG2. The P-type channel region 5 is a semiconductor region doped with a P-type impurity. In a case where a predetermined voltage is applied between the first trench gate TRG1 and the second trench gate TRG2, a channel that is a path of a signal charge is formed in the P-type channel region 5.

Thus, the pixel cell 3 includes the P-type channel region 5 with a conductivity type opposite to that of the floating diffusion FD in a region where a channel of the transfer transistor TRS is formed. Thereby, the pixel cell 3 can suppress dark current hat is provided by an electric charge that is generated in a neighborhood of the transfer transistor IRS independently of incident light and flows into the floating diffusion FD.

Additionally, the pixel cell 3 includes the first trench gate TRG1 and the second trench gate TRG2 that interpose both sides of the P-type channel region 5. Thereby, a predetermined voltage is applied between the first trench gate TRG1 and the second trench gate TRG2 in the pixel cell 3, and thereby, an energy barrier of a channel of the transfer transistor TRS can be lowered enough to transfer a signal charge. Therefore, according to the pixel cell 3, a transfer characteristic of a signal charge can be improved as compared with, for example, another pixel cell with a trench gate that is provided at only one side of the P-type channel region 5.

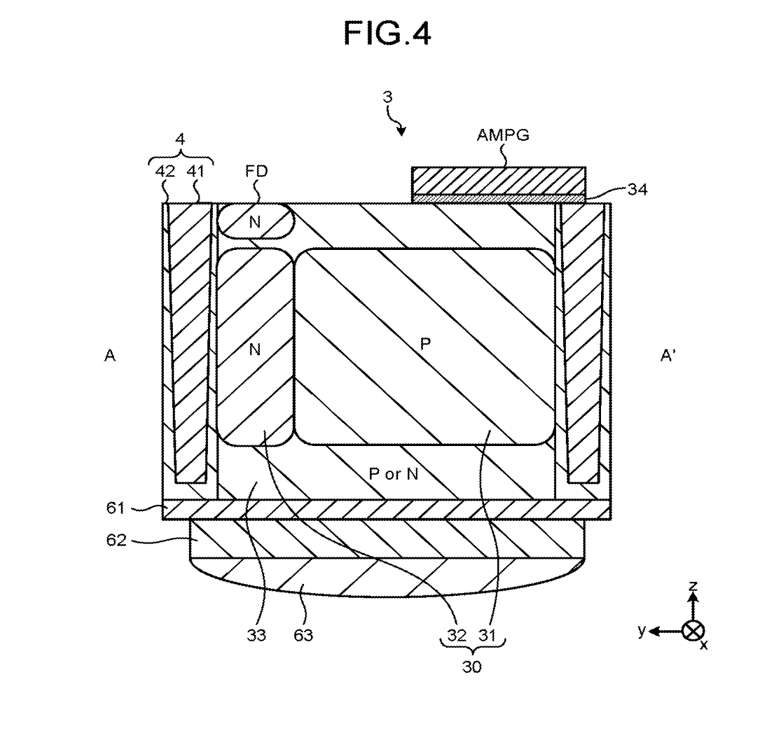

Next, a transfer path of a signal charge in the transfer transistor TRS in conjunction with cross-sectional structures of the pixel cell 3 according to the embodiment with reference to FIG. 4 to FIG. 6. FIG. 4 to FIG. 6 are diagrams illustrating cross sections of the pixel cell 3 according to the embodiment and a transfer path of a signal charge therein. In FIG. 4 to FIG. 6, components identical to those illustrated in FIG. 3 among components of the pixel cell 3 will be provided with reference numerals or letters identical to the reference numerals or letters illustrated in FIG. 3.

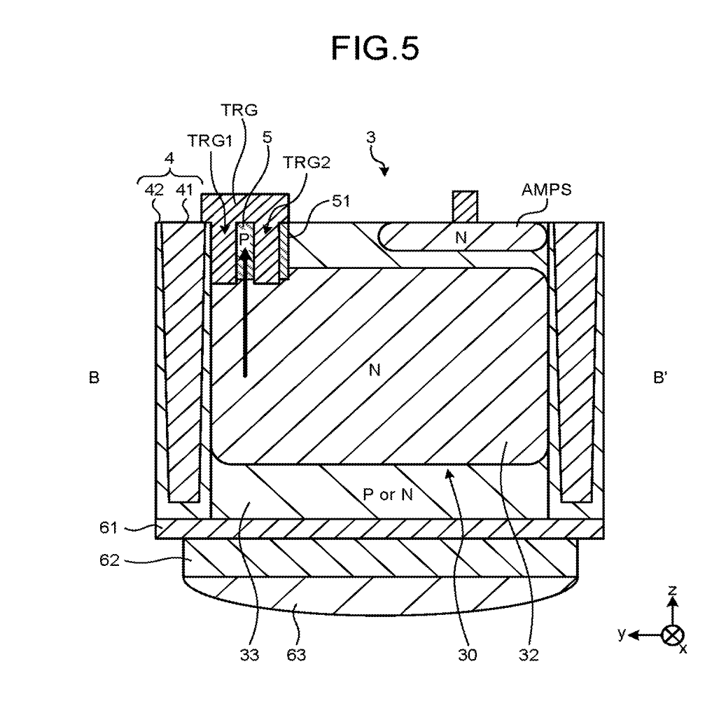

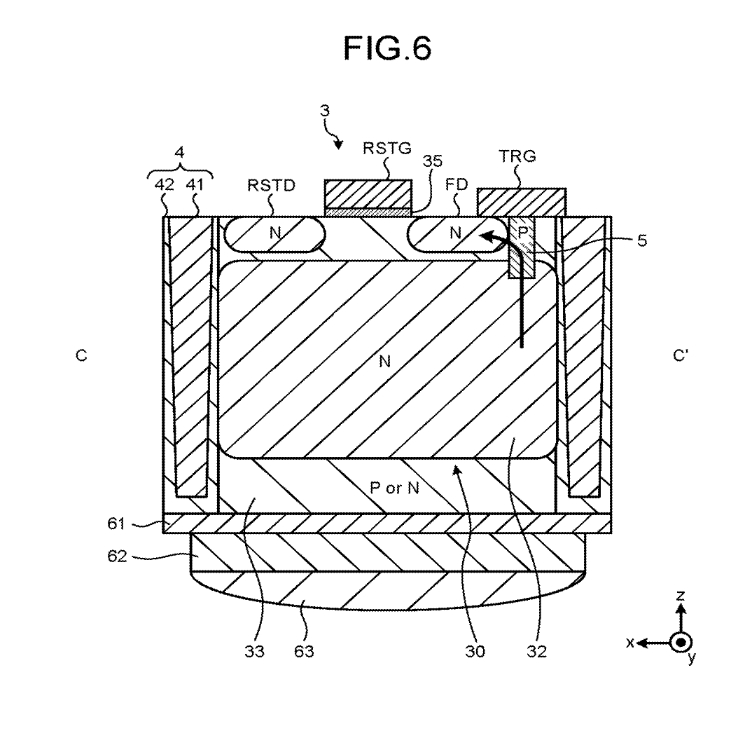

FIG. 4 illustrates a cross section of the pixel cell 3 with respect to line A-A′ in FIG. 3, FIG. 5 illustrates a cross section of the pixel cell 3 with respect to line B-B′ in FIG. 3, and FIG. 6 illustrates a cross section of the pixel cell 3 with respect to line C-C′ in FIG. 3. Thick arrows illustrated in FIG. 5 and FIG. 6 illustrate a flow of a signal charge.

As illustrated in FIG. 4, the pixel cell 3 includes the photoelectric conversion element 30 inside a P-type or N-type semiconductor layer 33 with side faces surrounded by the element separation region 4, and includes an antireflection film 61, a color filter 62, and a microlens 63 at a side of a back face of the semiconductor layer 33.

The element separation region 4 is a DTI (Deep Trench Isolation), and includes an insulating member 41 that is embedded in a trench that is formed in a direction of a depth of the semiconductor layer 33 from a front face of the semiconductor layer 33, and a region 42 doped with a P-type impurity that is provided on side faces and a bottom face of the insulating member 41.

As illustrated in FIG. 4, the photoelectric conversion element 30 includes the P-type semiconductor region 31 and the N-type charge storage region 32 that are adjacent to each other and extend in a direction of a depth of the semiconductor layer 33. Thereby, the photoelectric conversion element 30 has an increased P-N junction area in a direction of a depth of the semiconductor later 33 without increasing a surface area of a light-receiving face thereof, and thereby, a light-receiving sensitivity thereof can be improved.

The photoelectric conversion element 30 has the charge storage region 32 that extends in a direction of a depth of the semiconductor layer 33, and thereby, the number of saturation electrons of the charge storage region 32 can be increased without increasing a light-receiving surface area. The photoelectric conversion element 30 photoelectrically converts light incident on a side of a back face of the semiconductor layer 33 into, and stores in the charge storage region 32, a signal charge.

The floating diffusion FD is provided at a position shallower than that of the photoelectric conversion element 30 in the semiconductor layer 33. The amplification gate AMPG is provided on a front face of the semiconductor layer 33 through a gate insulating film 34.

As illustrated in FIG. 5, the source AMPS of the amplification transistor AMP is provided at a position shallower than that of the photoelectric conversion element 30 in the semiconductor layer 33. The drain AMPD (see FIG. 3) of the amplification transistor AMP is also provided a position shallower than that of the photoelectric conversion element 30 in the semiconductor layer 33, similarly to the source AMPS.

The transfer gate TRG is of a so-called double trench structure that includes the first trench gate TRG1 and the second trench gate TRG2 that reach a top face of the charge storage region 32 of the photoelectric conversion element 30 from a front face of the semiconductor layer 33. The P-type channel region is provided between the first trench gate TRG1 and the second trench gate TRG2.

In the present embodiment, a P-type channel region 51 doped with a P-type impurity is also formed on a side face at a side opposite to a side face of the second trench gate TRG2 at a ride that faces the first trench gate TRG1 in a manufacturing process. That is, the P-type channel region 51 is also formed to contact the second trench gate TRG2 at a position that is opposed to the P-type channel region 5 while the trench gate TRG2 is interposed therebetween.

The P-type channel region 5 may be configured to include a region that is interposed between the first trench gate TRG1 and the second trench gate TRG2 and surround an entirety of a portion of the transfer gate TRG that is embedded in the semiconductor layer 33.

In other words, the transfer gate TRG may be configured in such a manner that the first trench gate TRG1 and the second trench gate TRG2 are embedded inside a P-type channel region that is provided in a surface layer of the semiconductor layer 33.

A illustrated in FIG. 6, the drain RSTD of the reset transistor RST provided at a position comparable with a depth of the floating diffusion in the semiconductor layer 33. The reset gate RSTG is provided on a front face of the semiconductor layer 33 through a gate insulating film 35. As illustrated in the same drawing, the P-type channel region 5 is provided at a position where a side face thereof contacts the floating diffusion FD.

Thus, the pixel cell 3 includes the P-type channel region 5 with an opposite conductivity type between the N-type floating diffusion ED and the charge storage region 32. Thereby, in a case where a voltage is not applied to the transfer gate TRG, namely, in a case where the transfer transistor IRS is OFF, the pixel cell 3 can suppress dark current that is provided by an electric charge that is generated independently of incident light and flows into the floating diffusion FD.

In a case where a signal charge is transferred from the charge storage region 32 to the floating diffusion FD in the pixel cell 3, a predetermined voltage is applied to the transfer gate TRG to form a channel in the P-type channel region 5 and turn ON the transfer transistor TRS.

Thereby, a signal charge is pulled up from the charge storage region 32 to the P-type channel region 5, as indicated by a thick arrow in FIG. 5, and transferred to the floating diffusion FD, as indicated by a thick arrow in FIG. 6.

Herein, a voltage is applied between both sides of the P-type channel region 5 by the first trench gate TRG1 and the second trench gate TRG2, and hence, a height of an energy barrier is more greatly lowered than a case where a voltage is applied to one side thereof. Thereby, the pixel cell 3 can improve a transfer characteristic of a signal charge, for example, as compared with another pixel cell with a trench gate that is present at only one side of the P-type channel region 5.

As illustrated in FIG. 5, the pixel cell 3 also includes the P-type channel region 51 doped with a P-type impurity at a side face of the second trench gate TRG2 at a side opposite to a side where the P-type channel region is provided. For this reason, an electric charge is applied to the transfer gate TRG in the pixel cell 3, and thereby, a channel can also be formed in the P-type channel region 51.

Thereby, in the pixel cell 3, a signal charge is transferred from the charge storage region 32 to the floating diffusion FD through two formed channels such as the P-type channel regions 5 and 51, and thereby, a transfer characteristic of a signal charge can be further improved.

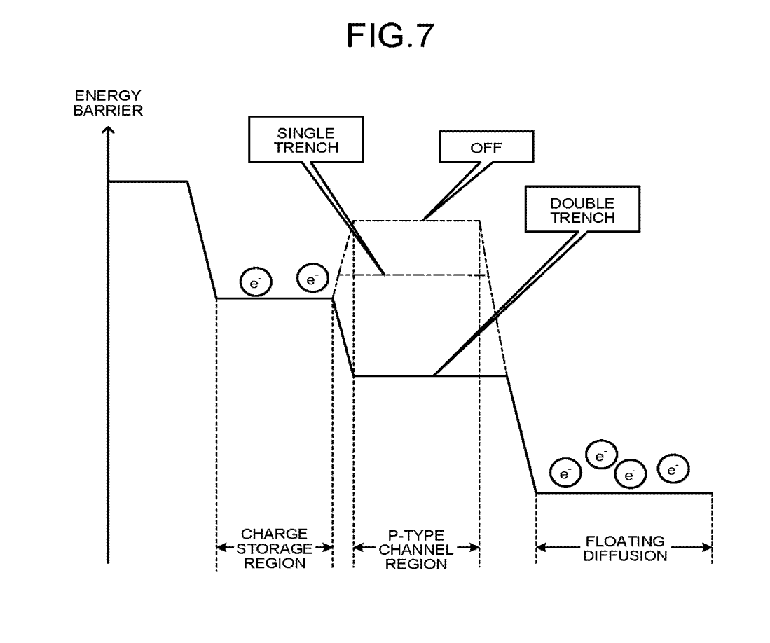

Next, an energy barrier of the transfer transistor TRS according to the embodiment will be described with reference to FIG. 7. FIG. 7 is a diagram illustrating an energy barrier of the transfer transistor TRS according to the embodiment in an ON/OFF state thereof.

As illustrated in FIG. 7, an energy barrier of the P-type channel region 5 is highest in an OFF state of the transfer transistor TRS where a voltage is not applied to the transfer gate TRG, as indicated by a two-dot chain line in the same drawing. Thereby, a signal charge is stored in the charge storage region 32.

Herein, for example, in a case where one trench gate is provided and a voltage is applied to the trench gate (a single trench is turned ON), an energy barrier of the P-type channel region 5 cannot sufficiently be lowered, as indicated by a one-dot chain line in the same drawing. In such a case, a signal charge may remain in the charge storage region 32 without being transferred therefrom. A signal charge that remains in the charge storage region 32 causes a residual image to be generated in a picked up image.

On the other hand, a voltage is applied between the first trench gate TRG1 and the second trench gate TRG2 (a double trench is turned ON) in the transfer transistor TRS according to the embodiment, and hence, an energy barrier of the P-type channel region 5 can be lowered sufficiently as indicated by a solid line in the same drawing. Therefore, the pixel cell 3 prevents a residue of a signal charge from being generated in the charge storage region 32, and thereby, can prevent a residual image from generating in a picked up image.

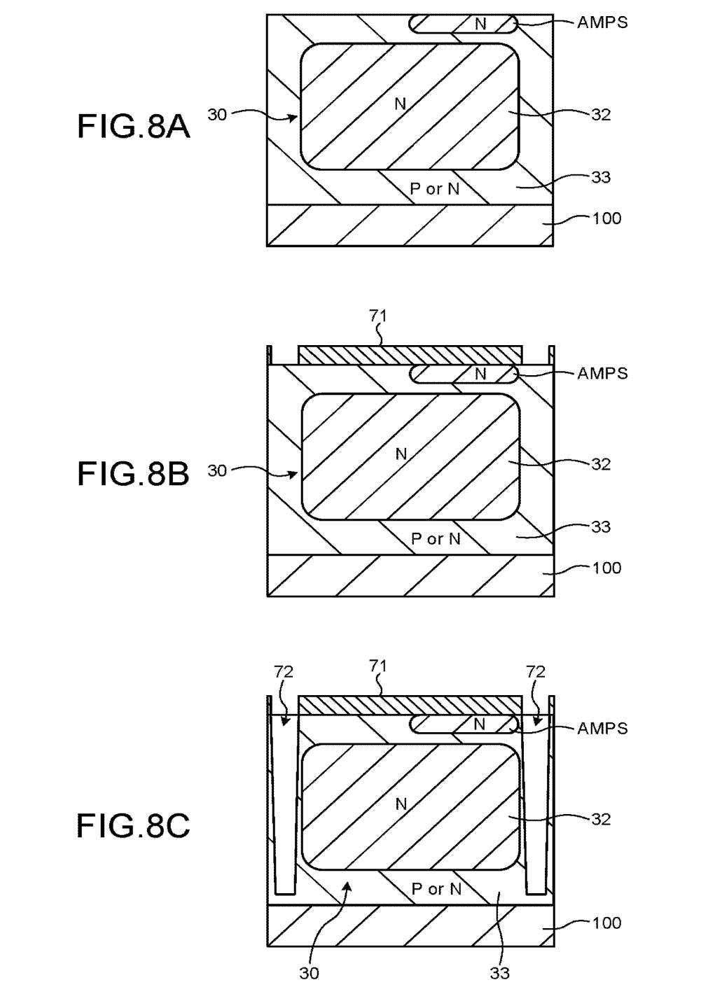

Next, a method for manufacturing the pixel cell 3 according to the embodiment will be described with reference to FIG. 8A to FIG. 11B. FIG. 8A to FIG. 11B are cross-sectional diagrams illustrating a process for manufacturing the pixel cell 3 according to the embodiment. Herein, a process for manufacturing the part of the pixel cell 3 as illustrated in FIG. 5 will be described in detail while the parts as illustrated in FIG. 4 and FIG. 6 will be described simply.

In a case where the pixel cell 3 is manufactured, first, a P-type or N-type silicon layer is epitaxially grown on, for example, a semiconductor substrate 100 such as a silicon wafer, to form a semiconductor layer 33, as illustrated in FIG. 8A.

Then, for example, a P-type impurity such as boron is ion-implanted into the semiconductor layer 33, and further, for example, an N-type impurity such as phosphorus is ion-implanted into the semiconductor layer 33. Subsequently, an anneal process is executed to activate an N-type charge storage region 32 and a P-type semiconductor region 31 (see FIG. 4), and thereby, a photoelectric conversion element 30 is formed.

Then, an N-type impurity such as phosphorus is ion-implanted into a shallow position at a side of one surface of the semiconductor layer 33, for example, a position shallower than that of the photoelectric conversion element 30, and an anneal process is conducted to form a source AMPS of an amplification transistor AMP.

At this time, similarly, for example, an N-type impurity such as phosphorus is also ion-implanted into positions for formation of a drain AMPD of the amplification transistor AMP, a drain RSTD of a reset transistor RST, and a floating diffusion FD, and an anneal process is executed.

Thereby, the drain AMPD of the amplification transistor AMP, the drain RSTD of the reset transistor RST, and the floating diffusion FD are formed simultaneously with the source AMPS of the amplification transistor AMP (see FIG. 3).

Then, a resist film 71 is formed on a front face of the semiconductor layer 33 and patterning is applied to the resist film 71 to expose a surface of the semiconductor layer 33 at a position for formation of an element separation region 4 (see FIG. 3) as illustrated in FIG. 8B.

Subsequently, while the resist film 71 is used as a mask, for example, RIE (Reactive Ion Etching) is executed to form a trench 72 for DTI that extends from a side of a front face to a side of a back face of the semiconductor layer 33, as illustrated in FIG. 8C.

Then, for example, a P-type impurity such as boron is ion-implanted toward inner peripheral faces of the trench 72 in oblique directions. At this time, ion implantation is divided into multiple times and executed while directions of ion irradiation are changed. Thereby, boron ion implantation is applied to entire inner peripheral faces of the trench 72.

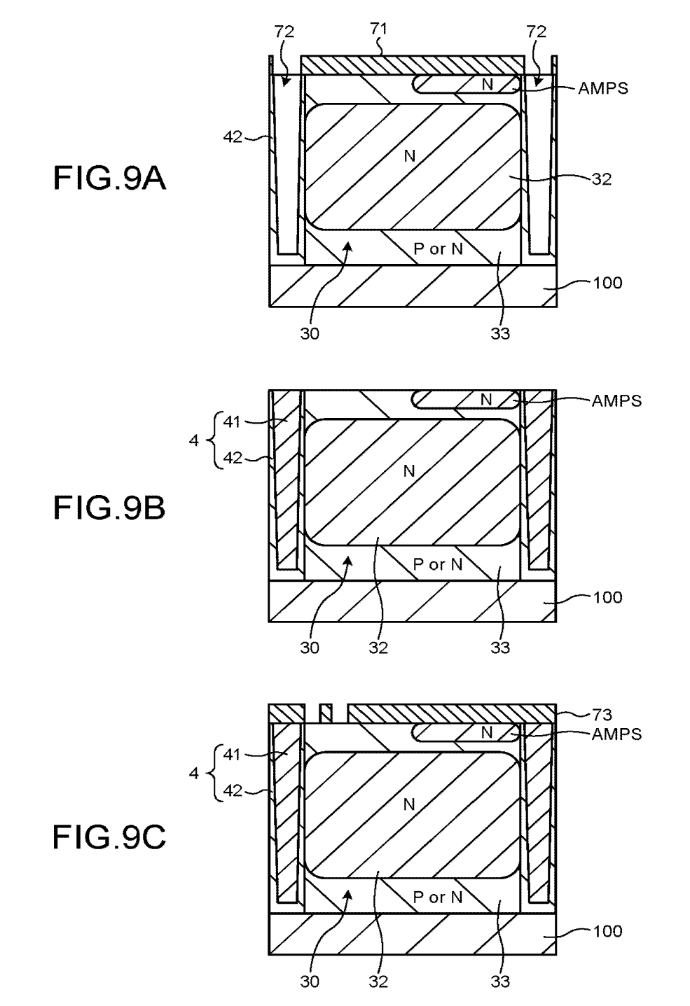

Subsequently, an anneal process is executed to form a region 42 doped with a P-type impurity on inner peripheral faces and a bottom face of the trench 72 as illustrated in FIG. 9A. Then, after the resist film 71 is stripped, an insulating member 41 such as silicon oxide is embedded by, for example, CVD (Chemical vapor Deposition) to form the element separation region 4, as illustrated in FIG. 9B.

Subsequently, a resist film 73 is formed on a front face of the semiconductor layer 33 as illustrated in FIG. 9C. Then, the resist film 73 is patterned to expose surfaces of the semiconductor layer 33 at positions for formation of a first trench gate TRG1 and a second trench gate TRG2 (see FIG. 3). At this time, the resist film 73 is patterned in such a manner that surfaces of the semiconductor layer 33 at exposed portions have a substantially circular shape.

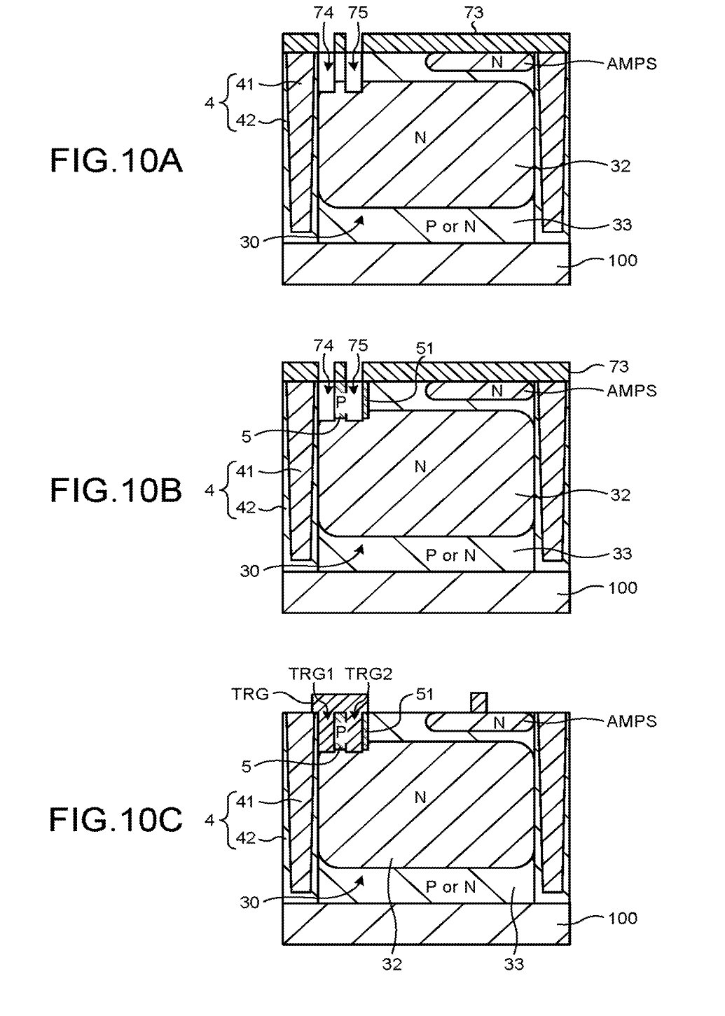

Subsequently, while the resist film 73 is used as a mask, for example, RIE is executed. Thereby, a trench 74 for the first trench gate TRG1 and a trench 75 for the second trench gate TRG2 are formed that extend from a side of a front face of the semiconductor layer 33 toward a aide of the photoelectric conversion element 30, as illustrated in FIG. 10A.

Then, for example, a P-type impurity such as boron is divided into multiple times and ion-implanted into a region that is interposed between the two trenches 74 and 75, in oblique directions, while directions of ion irradiation are changed. At this time, boron is also ion-implanted into a side face of the trench 75 that does not contact the element separation region 4, among the two trenches 74 and 75, at a side opposite to a region interposed between the two trenches 74 and 75

Subsequently, an anneal process is executed to form a P-type channel region 5 between the two trenches 74 and 75 that have a substantially solid circular cylindrical shape. At this time, a P-type channel region 51 doped with a P-type impurity is also formed at a side face of the trench 75 that does not contact the element separation region 4, at a side opposite to a side that contacts the type channel region 5.

Subsequently, after the resist film 73 is stripped, a conductive member such as polysilicon is laminated on a front face of the semiconductor layer 33 by, for example, CVD, and the conductive member is eliminated at an unwanted portion. Thereby, a transfer gate TRG that includes the first trench gate TRG1 and the second trench gate TRG2 is formed as illustrated in FIG. 10C. At this time, a reset gate RSTG and an amplification gate AMPG are formed simultaneously (see FIG. 3).

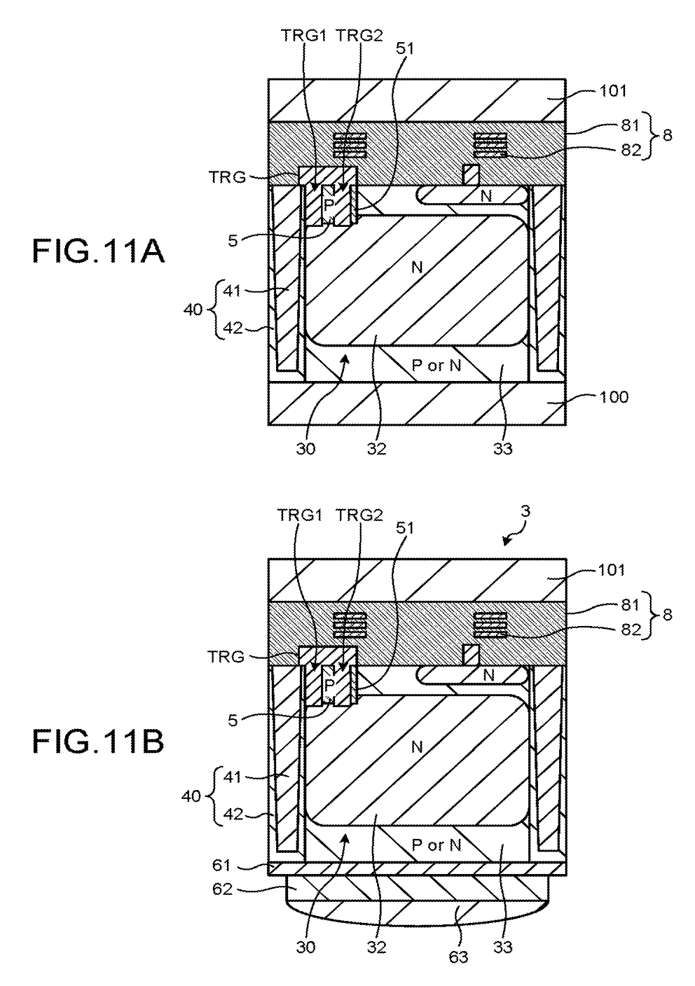

Then, a multilayer interconnection layer 8 is formed on a front face of the semiconductor layer 33, and for example, a supporting substrate 101 such as a silicon wafer is bonded to a front face of the multilayer interconnection layer 8, as illustrated in FIG. 11A. The multilayer interconnection layer 8 is formed by, for example, repeating a series of processes where an interlayer insulating film 81 such as silicon oxide is formed on a front face of the semiconductor layer 33, grooves for interconnections are patterned in the interlayer insulating film 81, and a metal such as copper is embedded in the grooves to form multilayer interconnections 82.

Subsequently, in a state that the supporting substrate 101 is supported, the semiconductor substrate 100 is ground and polished from a side of a back face thereof to expose a back face of the semiconductor layer 33. After an antireflection film 61 is formed of, for example, silicon nitride, on an exposed back face of the semiconductor layer 33, a color filter 62 and a microlens 63 are sequentially formed on a back face of the antireflection film 61 to complete the pixel cell 3, as illustrated in FIG. 11B.

As described above, a solid-state image pickup device according to the embodiment includes a semiconductor layer, a photoelectric conversion element that is provided in the semiconductor layer, and a floating diffusion that is provided at a shallow position at a side of one surface of the semiconductor layer. The solid-state image pickup device includes a plurality of trench gates that extend from a front face of the semiconductor layer toward the photoelectric conversion element in a direction of a depth of the semiconductor layer, next to the floating diffusion, and includes a semiconductor region with a conductivity type opposite to that of the floating diffusion, between the trench gates.

In a case where a voltage is riot applied between the trench gates in such a solid-state image pickup device, the semiconductor region that is provided between the trench gates has a conductivity type opposite to that of the floating diffusion, and hence, a barrier is provided against dark current that flows into the floating diffusion.

Therefore, in a case where a voltage is not applied between the trench gates in the solid-state image pickup device according to the embodiment, an inflow of an electric charge that is generated independently of incident light, into a floating diffusion, can be suppressed.

A voltage is applied between the plurality of trench gates in the solid-state image pickup device, and thereby, the voltage can he applied between both sides of the semiconductor region between the trench gates. Therefore, an energy barrier of the semiconductor region between the trench gates in the solid-state image pickup device is lowered enough to transfer a signal charge from the photoelectric conversion element to the floating diffusion, and thereby, a transfer characteristic of a signal charge can be improved.

The semiconductor region that is provided between the trench gates according to the embodiment contacts the floating diffusion. Thereby, a voltage is applied between the trench gates in the solid-state image pickup device, and thereby, a channel can be formed up to a neighborhood of the floating diffusion so that a transfer characteristic of a signal charge can further be improved.

Any of the trench gates according to the embodiment is of a substantially solid circular cylindrical shape. For this reason, for example, a resist film with simple and substantially circular holes patterned at positions for formation of the trench gates in the semiconductor layer can be used as a mask that is used in a case where the trench gates are produced, and complicated patterning does not have to be applied to the resist film.

Although a case where the first trench gate TRG1 and the second trench gate TRG2 are of a substantially solid circular cylindrical shape has been described in the embodiment described above, shapes of the first trench gate TRG1 and the second trench gate TRG2 are not limited thereto.

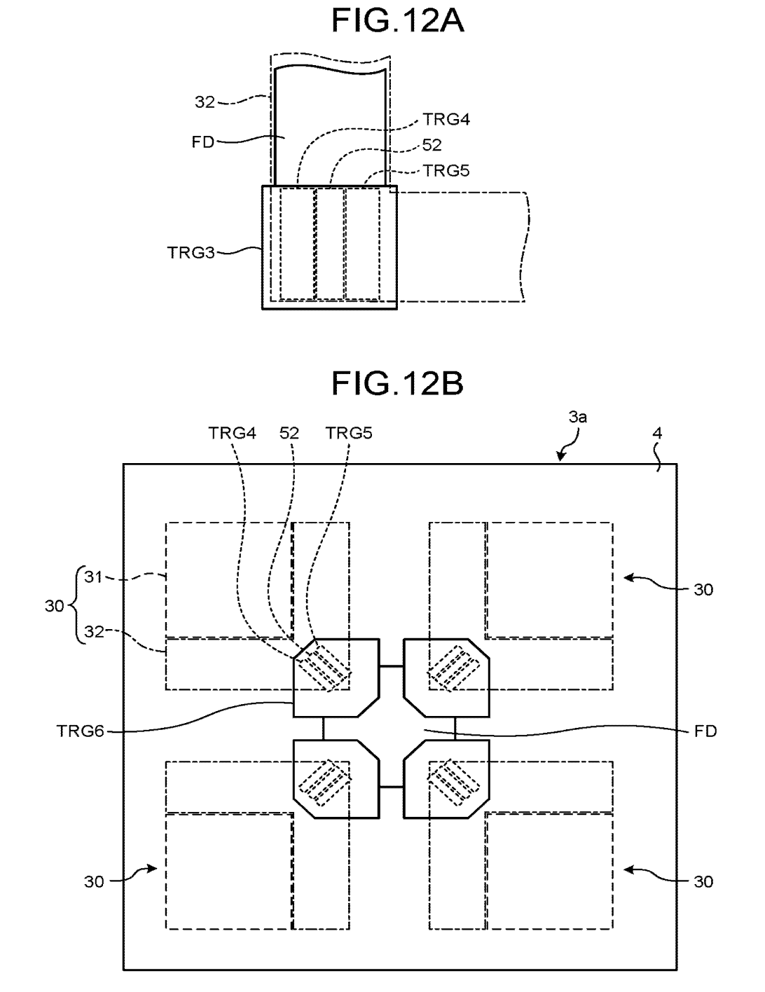

Hereinafter, variation examples of the embodiment will be described with reference to FIG. 12A and FIG. 12B. FIG. 12A and FIG. 12B are diagrams illustrating pixel cells according to variation examples of the embodiment. FIG. 12A selectively illustrates a portion near a transfer gate TRG3 of a pixel cell according to variation example 1. FIG. 12B illustrates a pixel cell 3a according to variation example 2.

The pixel cell according to variation example 1 has a configuration similar to that of the pixel cell 3 illustrated in FIG. 3 except that shapes of a first trench gate TRG4, a second trench gate TRG5, and a P-type channel region 52 doped with a P-type impurity are different from those of the transfer gate TRG illustrated in FIG. 3.

As illustrated in FIG. 12A, the transfer gate TRG3 of the pixel cell according to variation example includes the first trench gate TRG4 and the second trench gate TRG5 that are adjacent to a floating diffusion FD and are of a plate shape.

The pixel cell according to variation example 1 includes a P-type channel region 52 that faces the floating diffusion FD, between the first trench gate TRG4 and the second trench gate TRG5.

Any of the first trench gate TRG4 and the second trench gate TRG5 extends from a front face of the semiconductor layer 33 toward the floating diffusion FD, and principal surfaces thereof are opposed to one another. Principal surfaces herein are side faces with a largest surface area among side faces of the first trench gate TRG4 and the second trench gate TRG5. Herein, principal surfaces are surfaces that face the P-type channel region 52 among side faces of the first trench gate TRG4 and the second trench gate TRG5.

The P-type channel region 52 can be extended in the pixel call according to variation example 1, and hence, an inflow of dark current into the floating diffusion FD can be further suppressed in a case where a transfer transistor is OFF.

Additionally, in a case where a voltage is applied between the first trench gate TRG4 and the second trench gate TRG5 in the pixel cell according to variation example 1, an extended P-type channel region 52 becomes a channel, and hence, a transfer characteristic of a signal charge can be further improved.

Although a case where one floating diffusion FD Is provided for one photoelectric conversion element 30 has ever been provided as an example, the pixel cell according to the embodiment may be configured in such a manner that a plurality of photoelectric conversion elements 30 share one floating diffusion FD.

For example, a configuration may be provided in such a manner that four photoelectric conversion elements 30 share one floating diffusion FD, like the pixel cell 3a in variation example 2 as illustrated in FIG. 12B. Each photoelectric conversion element 30 illustrated in FIG. 12B has a configuration identical to that of the photoelectric conversion element 30 illustrated in FIG. 3.

In a case where such a configuration is provided, for example, the four photoelectric conversion elements 30 are provided as a two-by-two matrix in the pixel cell 3a as illustrated in FIG. 12B. Each photoelectric conversion element 30 is arranged in such a manner that a corner portion of an L-shape of a charge storage region 32 with an L-shape in a planar view is directed to a center of the pixel cell 3a. Electrical element separation between respective photoelectric conversion elements 30 is attained by an element separation region 4.

A floating diffusion FD is provided at a shallow position at a side of one surface of a semiconductor layer, for example, a position shallower than those of the photoelectric conversion elements 30, at a center of the pixel cell 3a. A transfer gate TRG6 is provided that includes a first trench gate TRG4 and second trench gate TRG5 that extend from a front face of the semiconductor layer toward a corner portion of an L-shape in each charge storage region 32.

A P-type channel region 52 is each provided between the first trench gate TRG4 and the second trench gate TRG5. Shapes of the first trench gate TRG4, the second trench gate TRG5, and the P-type channel region are identical to those illustrated in FIG. 12A.

Thereby, in the pixel cell 3a with a so-celled four-pixel one-cell structure, a transfer characteristic of a signal charge from each of the four photoelectric conversion elements 30 to the floating diffusion ED can also be improved while an inflow of dark current into the floating diffusion FD is suppressed.

Although a case where the first trench TRG4 and the second trench gate TRG5 in the pixel cell 3a illustrated in FIG. 12B are of a plate shape has been described, the first trench gate TRG4 and the second trench gate TRG5 may be of a substantially solid circular cylindrical shape (see FIG. 3).

Although the embodiment and variation examples described above have been described by providing, as an example, a case where a transfer gate includes two trench gates, the transfer gate according to the embodiment may be configured to include three or more trench gates.

In such a case, a P-type semiconductor region doped with a P-type impurity is each provided between the three or more trench gates, and the trench gates are arrayed in a line in a planar view at positions where all of the P-type semiconductor regions between trenches face or contact a floating diffusion.

Although a case where a pixel cell includes a P-type channel region with a conductivity type opposite to that of a floating diffusion between a plurality of trench gates has been described in the embodiment described above, a conductivity type of the channel region may be identical to that of the floating diffusion.

For example, a case where a state of an interface between a trench gate and a semiconductor layer is good and a few crystal defect is present on the interface or a case where dark current does not have to be taken into consideration depending on a design of a voltage to be applied between trench gates may be provided. In such a case, a pixel cell may be configured to include an N-type semiconductor region as a channel region between a plurality of trench gates. In a case where a conductivity type of a semiconductor layer is N-type, a concentration of an N-type impurity in a channel region is higher than a concentration of an N-type impurity in the semiconductor layer.

Thereby, a transfer characteristic (ease of transfer) of a signal charge from a photoelectric conversion element to a floating diffusion is improved in the pixel cell. Additionally, in a case where a transfer transistor in the pixel cell is turned ON, a voltage is applied between both sides of a channel region by two trench gates, and hence, a signal charge transfer capability of the transfer transistor is increased.

That is, a solid-state image pickup device according to the embodiment produces an effect of improvement of potential swing capability due to a double gate described with reference to FIG. 7, even if the channel regions 5, 51, and 52 are N-type.

Therefore, in a case where a transfer transistor in such a pixel cell is turned ON, a residue of a signal charge in a photoelectric conversion element can be suppressed, and hence, generation of a residual image in a picked up image can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state image pickup device, comprising:
a semiconductor layer;
a photoelectric conversion element that is provided in the semiconductor layer;
a floating diffusion that is provided at a shallow position at a side of one surface of the semiconductor layer;
a plurality of gates that are each provided adjacent to the floating diffusion and extend toward the photoelectric conversion element in a direction of a depth of the semiconductor layer; and
a semiconductor region that provided between the gates to face the floating diffusion.

2. The solid-state image pickup device as claimed in claim 1, wherein a conductivity type of the semiconductor region is opposite to that of the floating diffusion.

3. The solid-state image pickup device as claimed in claim 1, wherein a conductivity type of the semiconductor region is identical to that of the floating diffusion.

4. The solid-state image pickup device as claimed in claim 1, wherein the plurality of gates are of a substantially solid circular cylindrical shape.

5. The solid-state image pickup device as claimed in claim 1, wherein the plurality of gates are of a plate shape and principal surfaces thereof are opposed to one another.

6. The solid-state image pickup device as claimed in claim 1, wherein the photoelectric conversion element includes:
a region with a quadrangular prismatic shape and a conductivity type being P-type that is provided inside the semiconductor layer; and
a region with an L-shape in a planar view and a conductivity type being N-type that is provided along two adjacent side faces of the region with a conductivity type being P-type.

7. The solid-state image pickup device as claimed in claim 6, wherein the floating diffusion is provided over the region with a conductivity type being N-type.

8. The solid-state image pickup device as claimed in claim 6, wherein the gates reach a top face of the region with a conductivity type being N-type from a front face of the semiconductor layer.

9. The solid-state image pickup device as claimed in claim 1, further comprising
a semiconductor region that is provided at a position that is opposed to the semiconductor region while the gate is interposed therebetween.

10. The solid-state image pickup device as claimed in claim 1, wherein the gates are embedded inside the semiconductor region that is provided in a surface layer of the semiconductor layer.

11. The solid-state image pickup device as claimed in claim 1, wherein the semiconductor region is provided at a position where a side face thereof contacts the floating diffusion.

12. The solid-state image pickup device as claimed in claim 6, wherein
four of the photoelectric conversion elements are provided as a two-by-two matrix in a pixel cell and are each arranged in such a manner that a corner portion of the L-shape of the region with an L-shape in a planar view and a conductivity type being N-type is directed to a center of the pixel cell,
the floating diffusion is provided at a position shallower than those of the photoelectric conversion elements in the semiconductor layer at a center of the pixel cell, and
the gates each extend from a front face of the semiconductor layer toward the corner portion of the L-shape of the region with a conductivity t e being N-type.

13. A method for manufacturing a solid-state image pickup device, comprising:
forming a photoelectric conversion element in a semiconductor layer;
forming a floating diffusion at a shallow position at a side of one surface of the semiconductor layer;
forming, adjacent to the floating diffusion, a plurality of trenches that extend toward the photoelectric conversion element in a direction of a depth of the semiconductor layer;
forming a semiconductor region between the plurality of trenches; and
embedding a conductive member in the trenches to form gates.

14. The method for manufacturing a solid-state image pickup device as claimed in claim 13, wherein the forming a semiconductor region includes
forming the semiconductor region with a conductivity type opposite to that of the floating diffusion.

15. The method for manufacturing a solid-state image pickup device as claimed in claim 13, wherein the forming trenches includes
forming the trenches with a hollow circular cylindrical shape.

16. The method for manufacturing a solid-state image pickup device as claimed in claim 13, wherein the forming a semiconductor region includes
executing implantation of an impurity toward a region interposed between the plurality of trenches in an oblige direction while a direction of irradiation with the impurity is changed.

17. The method for manufacturing a solid-state image pickup device as claimed in claim 16, wherein the forming a semiconductor region includes
implanting the impurity into both side faces of the trench.

18. The method for manufacturing solid-state image pickup device as claimed in claim 13, wherein the forming a photoelectric conversion element includes:
forming a region with a quadrangular prismatic shape and a conductivity type being P-type inside the semiconductor layer; and
forming a region with an L-shape in a planar view and a conductivity type being N-type along two adjacent side faces of the region with a conductivity type being P-type.

19. The method for manufacturing a solid-state image pickup device as claimed in claim 18, wherein the forming a floating diffusion includes
forming the floating diffusion over the region with a conductivity type being N-type.

20. The method for manufacturing a solid-state image pickup device as claimed in claim 18, wherein the forming trenches includes
forming the trenches that reach a top face of the region with a conductivity type being N-type from a front face of the semiconductor layer.
